(19) United States
(12) Patent Application Publication
(10) Pub. No.: US 2009/0212805 A1
(43) Pub. Date: Aug. 27, 2009

(54) PROBE OF VERTICAL PROBE CARD

(75) Inventors: Been-long Chen, Hsin-Chu City (TW); Huang-chih Chen, Hsin-Chu City (TW)

Correspondence Address: KIRTON AND MCCONKIE, 60 EAST SOUTH TEMPLE,, SUITE 1800, SALT LAKE CITY, UT, 84111, US

(73) Assignee: IPWORKS TECHNOLOGY CORP., Hsin-Chu (TW)

(21) Appl. No.: 12/177,525

(22) Filed: Jul. 22, 2008

(30) Foreign Application Priority Data
Feb. 21, 2008 (TW) 097106042

(51) Int. Cl. G01R 1/067

(52) U.S. Cl. 324/761

(57) ABSTRACT

A probe of a vertical probe card is disclosed. The probe has a probe tip and a surface region extended from the probe tip about 1-10 mil. The surface region is coated with a nano-film of high electro-conductive nano-material, and the thickness of the nano-film is about 1-20 nm. The nano-film of the probe can efficiently provide excellent no-clean property and higher electro-conductivity for lowering contact force and elongating usage lifetime of the probe of vertical probe card. Accordingly the yield of wafer testing can be improved, the frequency of cleaning probe can be lowered, and the total testing cost can be reduced.

### FIELD OF THE INVENTION

The present invention relates to a probe of a probe card for a wafer probing test, and more particularly to a probe of a vertical probe card having a nano-film of electro-conductive nano-material on the probe.

### BACKGROUND OF THE INVENTION

A probe card is constructed by a multi-layer printed circuit board (PCB) which may include more than 30 layers. The probe card has complicated structure and provides a plurality of probes for being in contact with a plurality of electrical contacts (i.e. pads) on a wafer, respectively. Generally, a contact area between each of the probes and each of the electrical contacts of the wafer is smaller than a cross-sectional area of a hair. Before an integrated circuit (IC) die is packaged by encapsulant, the probe card can be used to test electrical functions of the IC die cut from a wafer, in order to remove defective dies and keep known good dies for the following packaging processes. Thus, a wafer probing test is one of important processes in the integrated circuit fabrication, which affects the manufacture cost thereof.

For the structure of a vertical probe card, it is provided with a plurality of probes, each of which has two ends electrically connected to a printed circuit board and a to-be-tested object, respectively. When a testing is under execution, a transiently electrical current is frequently passed through a contact area between a probe tip and a pad on the to-be-tested object. Especially, a device requested for high electrical current testing, it may cause the probes tip are burned out. As for device requested high temperature testing such as 75° C. or even 105° C., it may cause the die pad softened and easily wetted the probe tip. As a result, lowering the electro-conductivity of the probe, increasing the resistance of the probe, and affecting the test reliability and lifetime of the probe card.

Furthermore, the probes of the entire vertical probe card must be fully in contact with a to-be-tested die, in order to ensure the test quality of the vertical probe. However, for the vertical probe card, because the probe tip of the probe may be wetted with foreign matter (such as solder from the pad), the test quality may be lowered or the mis-test probability may be increased, resulting in unexpectedly lowering the test yield. Generally, to solve the foregoing problem, an overdrive contact force may be used to force the probe tip to tightly bear against the surface of the pad, so that the contact condition and the test yield and quality can be enhanced and improved. Nevertheless, if the overdrive contact force can be used to solve the foregoing problem and enhance the test yield, the overdrive contact force may damage other lower structure under the surface of the pad. Especially, when current technologies of advanced wafer processes (such as 0.13 μm, 90 nm, 65 nm, and etc.) are generally carried out on wafers made of fragile low-k dielectric material, the wafer probing test must prevent the low-k dielectric material and other lower structure/material thereof from being deformed or damaged. Although a cleaning method of the probes can be used to solve the foregoing problem. However, once the number of the probes is increased or the pitch between the adjacent probes is decreased, the cleaning frequency of the probes may be considerably increased, resulting in lowering the utility rate of test machines and shortening the lifetime of the probes.

The foregoing solder-wetted problem is generally occurred on the probes of the vertical probe card. Recently, although related manufacturers develop a kind of probe coated with a metal film to elongate the lifetime of the probe, the wetted problem still cannot be solved. As a result, the metal film still cannot enhance the test yield and the test stability.

### SUMMARY OF THE INVENTION

A primary object of the present invention is to provide a probe of a vertical probe card, which is used to stabilize the test quality of a wafer probing test, and prevent probes from being wetted with a to-be-tested die, so as to lower the cleaning frequency of the probes, enhance the utility rate of test machines, and increase the test yield of the dies for the purpose of reducing the entire test cost.

To achieve the above object, a preferred embodiment of the present invention provides a probe of a vertical probe card, wherein the vertical probe card comprises a plurality of probes (or at least one probe) which are mounted on a substrate and a nano-film of electro-conductive nano-material coated on each of the probes or all the surface of the substrate including the probes.

In the present invention, the vertical probe card can be preferably selected from a micro-electromechanical system (MEMS) micro-array probe card manufactured by a MEMS process or a vertical pin probe card.

According to the probe of a vertical probe card in the preferred embodiment of the present invention, the nano-film of electro-conductive nano-material can be preferably selected from electro-conductive nano-material having a no-clean property, and the thickness of the nano-film is preferably about 1-20 nanometer (nm).

According to the probe of the vertical probe card in the preferred embodiment of the present invention, the metal material of the probes can be preferably selected from the group consisting of nickel (Ni), gold (Au), copper (Cu), Palladium (Pd), Platinum (Pt), Silver (Ag), Zinc (Zn), tungsten (W), rhenium (Re), titanium (Ti), beryllium (Be), other electro-conductive metal, and alloy thereof. The structure of each of the probes can be preferably selected from a metal micro-spring or a metal pin.

According to the probe of the vertical probe card in the preferred embodiment of the present invention, the nano-film of electro-conductive nano-material is preferably coated on each of the probes by an evaporated and chemical plating process. The nano-film of electro-conductive nano-material is coated on a surface region of the probe vertically extended from a probe tip about 1-10 mil.

The present invention is related to a probe of a vertical probe card, which is applied a nano-film of electro-conductive nano-material to a surface region of the probe. Thus, according to of the present invention, the nano-film of the probe can efficiently provide better no-clean property, higher electro-conductivity, lower contact force, and longer usage lifetime for the probe of vertical probe card.

The present invention is related to a probe of a vertical probe card, which is used to stabilize the test quality of a wafer probing test by preventing from generating excessive attraction force between each of probes and each pad of a to-be-tested die, i.e. the probes can provide excellent no-clean property, so as to lower the cleaning frequency of the probes, enhance the utility rate of test machines, and increase the test yield of the dies for the purpose of reducing the entire test cost.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic view of a vertical probe card according to a preferred embodiment of the present invention; and

FIG. 2 is an enlarged schematic view of a nano-film on a probe tip of the probe, as shown in FIG. 1.

### DETAILED DESCRIPTION OF THE PREFERRED EMBODIMENTS

The present invention provides a probe of a vertical probe card, wherein the vertical probe card comprises a plurality of probes (or at least one probe) and a nano-film of electro-conductive nano-material. The probes are mounted on the vertical probe card and made of a metal material, while the nano-film of electro-conductive nano-material is coated on each of the probes.

In the present invention, the vertical probe card can be preferably selected from a micro-electromechanical system (MEMS) micro-array probe card manufactured by a MEMS process or a vertical pin probe card.

In the present invention, the nano-film of electro-conductive nano-material can be preferably selected from electro-conductive macromolecular having a no-clean property. For example, the electro-conductive nano-material can be selected from the group consisting of polypyrrole, polyparaphenylene, polythiophene, polyaniline, combination thereof, and derivative thereof. The thickness of the nano-film of electro-conductive nano-material is preferably about 1-20 nanometer (nm), especially about 1-10 nm.

In the present invention, the probes are made of the metal material which can be preferably selected from the group consisting of nickel (Ni), gold (Au), copper (Cu), Palladium (Pd), Platinum (Pt), Silver (Ag), Zinc (Zn), tungsten (W), rhenium (Re), titanium (Ti), beryllium (Be), other electro-conductive metal, and alloy thereof. The foregoing alloy can be preferably selected from rhenium-tungsten (Re—W) alloy or beryllium-copper (Be—Cu) alloy. The structure of each of the probes can be preferably selected from a metal micro-spring or a metal pin.

In the present invention, the nano-film of electro-conductive nano-material is preferably coated on each of the probes by an evaporated and chemical plating process. The nano-film of electro-conductive nano-material is coated on a surface region of the probe vertically extended from a probe tip about 1-10 mil.

In the present invention, the term “no-clean” refers to that there is no foreign matter (such as solder or flux residue) which remains on the probe tip of the probe after the probe tip is in contact with a pad on a to-be-tested die or wafer.

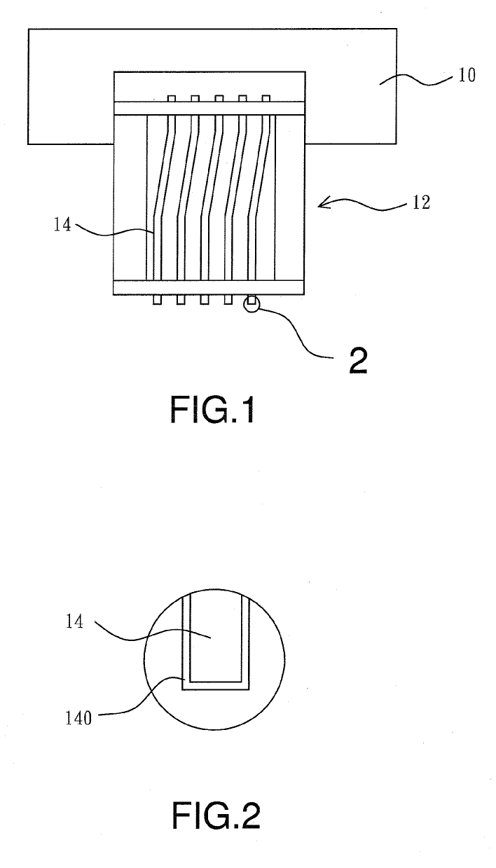

Referring now to FIG. 1, a schematic view of a probe of a vertical probe card according to a preferred embodiment of the present invention is illustrated. As shown in FIG. 1, the vertical probe card comprises a substrate 10, a guiding mechanism 12, and a plurality of probes 14, wherein the substrate 10 has a bottom surface formed with a plurality of protruded pads (not-shown). The guiding mechanism 12 is correspondingly mounted on the bottom surface of the substrate 10, while all of the probes 14 are movably disposed in the guiding mechanism 12. Each of the probes 14 has an upper end which is correspondingly mounted under each of the pads of the substrate 10 and a lower end (i.e. a probe tip) which is extended downward out of the guiding mechanism 12. Therefore, when the probe card is used to test a to-be-tested die (i.e. chip), the lower end of each of the probes 14 can bear against each of electrical contacts of the to-be-tested die. Meanwhile, based on the elasticity of each of the probes 14, the upper end thereof will be pushed and bear against each of the pads of the substrate 10. As a result, the to-be-tested die can be electrically connected to the substrate 10 of the probe card through the probes 14.

Referring now to FIG. 2, an enlarged schematic view of a nano-film on a probe tip of the probe in FIG. 1 is illustrated. According to the preferred embodiment of the present invention, the upper end (or the lower end) of each of the probes 14 is still coplanar in comparison with that of the original probe card. Because the thickness of the nano-film 140 is only about 1-20 nm, the size of the probes 14 is not apparently increased and the test quality of high-frequency probing is not affected. According to the preferred embodiment of the present invention, the structure of the probes 14, as shown in the enlarged schematic view of FIG. 2, is not limited to the basic structure of the vertical probe card. In the present invention, the probe tip of the probe 14 is coated with the nano-film 140 of electro-conductive nano-material for providing the effect of the present invention.

In the present invention, the substrate 10 can be preferably selected from a printed circuit board or a silicon substrate. The material of the vertical probes 14 can be preferably selected from various electro-conductive metal or alloy. The foregoing alloy can be preferably selected from Re—W alloy or Be—Cu alloy.

Furthermore, during transmitting electrical signals by the vertical probes 14, the probes 14 having the nano-film 140 of electro-conductive nano-material can provide excellent no-clean property, so that the probes 14 can be easily in contact with correct tested locations of the to-be-tested die without noise signal caused by wetted foreign matter. As a result, when the probes 14 transmit electrical signals, the noise signal can be prevented, so as to enhance the accuracy of signal transmission and the stability of wafer probing test.

Moreover, under the trend of applying low-k dielectric material to technologies of advanced wafer processes (such as 0.13 μm, 90 nm, 65 nm, and etc.), it is necessary to prevent the technology of wafer probing test from deforming or damaging the low-k dielectric material and other lower structure/material thereof. In the present invention, the probe 14 having the nano-film 140 can provide the no-clean property, so as to be advantageous to lower the contact force. In other words, it is only necessary for a test machine of the vertical probe card to set a minimum overdrive contact condition. As a result, the foregoing deformation/damage problem can be easily solved, and the test yield and quality can be efficiently enhanced.

In addition, in the present invention, the nano-film of the vertical probe card is directly coated on the surface region of each of the probes by an evaporated and chemical plating process, so that the length of the nano-film on the probe can be controlled by a precision plating fixture. In the preferred embodiment, the precision plating fixture can be easily designed according to simple parameters, such as the size of the substrate (such as printed circuit board or silicon substrate) and the relative pitch of the probes. Thus, in the present invention, it is unnecessary to change the original structure of the probe card before finishing an advance process of forming the nano-film of the probes. Meanwhile, in the present invention, the coplanarity of the probes of the vertical probe card will not be changed by the nano-film process. As a result, the yield and output quantity of the nano-film process can be apparently enhanced, while the time and cost of the entire manufacture process can be also lowered.

As described above, according to the probe of the vertical probe card provided by the present invention, the nano-film is formed on the probes of the vertical probe card, so as to be advantageous to increase the integration density and the pin amount, and shorten the pin pitch. Meanwhile, the nano-film on the vertical probe card of the present invention is manufactured by the precision plating fixture and related process technologies, so that the manufacture cost of the nano-film can be lowered and the yield thereof can be enhanced.

The present invention provides a probe of a vertical probe card, wherein a plurality of probes mounted on the vertical probe card are applied to the wafer probing test of semiconductor industry. When traditional probes are used to carry out the wafer probing test, the probe tip of the probes may be wetted with solder from the pads of a to-be-tested die. To solve the problem, a surface region of the probe in the present invention is coated with a nano-film of electro-conductive nano-material for preventing from generating excessive attraction force between the probes and the to-be-tested die, so that the probes can provide excellent no-clean property. As a result, the cleaning frequency of the probes can be lowered, the utility rate of test machines can be enhanced, and the test yield of the dies can be increased, so as to reduce the entire test cost.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A probe of a vertical probe card, comprising:
at least one probe made of a metal material and mounted on a vertical probe card; and
a nano-film of electro-conductive nano-material coated on each of the at least one probe.

2. The probe of claim 1, wherein the vertical probe card is a micro-electromechanical system (MEMS) micro-array probe card or a vertical pin probe card.

3. The probe of claim 1, wherein the nano-film of electro-conductive nano-material is electro-conductive macromolecular material having a no-clean property.

4. The probe of claim 3, wherein the electro-conductive nano-material is selected from the group consisting of polypyrrole, polyparaphenylene, polythiophene, polyaniline, combination thereof, and derivative thereof.

5. The probe of claim 1, wherein the thickness of the nano-film of electro-conductive nano-material is about 1-20 nm.

6. The probe of claim 4, wherein the thickness of the nano-film of electro-conductive nano-material is about 1-20 nm.

7. The probe of claim 1, wherein the thickness of the nano-film of electro-conductive nano-material is about 1-10 nm.

8. The probe of claim 4, wherein the thickness of the nano-film of electro-conductive nano-material is about 1-10 nm.

9. The probe of claim 1, wherein the metal material is selected from the group consisting of nickel, gold, copper, palladium, platinum, silver, zinc, tungsten, rhenium, titanium, beryllium, electro-conductive metal, and alloy thereof.

10. The probe of claim 9, wherein the alloy is rhenium-tungsten alloy or beryllium-copper alloy.

11. The probe of claim 1, wherein the probe is a metal micro-spring or a metal pin.

12. The probe of claim 1, wherein the nano-film of electro-conductive nano-material is coated on the probe by an evaporated and chemical plating process.

13. The probe of claim 1, wherein the nano-film of electro-conductive nano-material is coated on a surface region of the probe vertically extended from a probe tip of the probe about 1-10 mil.
